(19) United States
(12) Patent Application Publication
(10) Pub. No.: US 2023/0384808 A1
(43) Pub. Date: Nov. 30, 2023

(54) TEMPERATURE CONTROL SYSTEM

(71) Applicant: KELK Ltd., Kanagawa (JP)

(72) Inventors: Kazuhiro MIMURA, Kanagawa (JP); Atsushi KOBAYASHI, Kanagawa (JP); Hideaki OHKUBO, Kanagawa (JP)

(21) Appl. No.: 18/031,906

(22) PCT Filed: Oct. 13, 2021
(86) PCT No.: PCT/JP2021/037927

§ 371 Date: Apr. 14, 2023

(30) Foreign Application Priority Data
Oct. 16, 2020 (JP) 2020-174862

(51) Int. Cl. G05D 23/13

(52) U.S. Cl. CPC G05D 23/134; H01L 21/67248

(57) ABSTRACT

A temperature control system includes: a circulation channel which includes a temperature adjustment target and through which a circulation fluid that adjusts a temperature of the temperature adjustment target flows; a temperature adjuster that is arranged in the circulation channel and that adjusts a temperature of the circulation fluid supplied to the temperature adjustment target; a first temperature adjustment unit that is connected to the circulation channel via a first supply channel and that delivers a first fluid having a first temperature; a second temperature adjustment unit that is connected to the circulation channel via a second supply channel and that delivers a second fluid having a second temperature higher than the first temperature; a first valve arranged in the first supply channel; and a second valve arranged in the second supply channel. The second valve is an electromagnetic valve, and closes the second supply channel after opening the second supply channel when a set temperature of the temperature adjustment target is changed from a first set temperature to a second set temperature higher than the first set temperature.

### FIELD

The present disclosure relates to a temperature control system.

### BACKGROUND

In a technical field related to a semiconductor manufacturing device, a temperature control system as disclosed in Patent Literature 1 is used. In Patent Literature 1, a temperature control system includes a circulation channel including a temperature adjustment target, and a temperature adjustment unit arranged outside the circulation channel. When fluid is supplied from the temperature adjustment unit to the circulation channel, a temperature of the fluid flowing through the circulation channel is adjusted. A valve is arranged in a channel that connects the circulation channel and the temperature adjustment unit. When the valve is controlled, the fluid is supplied from the temperature adjustment unit to the circulation channel.

### CITATION LIST

### Patent Literature

Patent Literature 1: WO 2020/145082 A

### SUMMARY

### Technical Problem

When a response speed of a valve is low, there is a possibility that it takes a long time until a temperature of fluid that flows through a circulation channel is adjusted to a set temperature.

An object of the present disclosure is to adjust a temperature of fluid flowing through a circulation channel to a set temperature in a short time.

### Solution to Problem

According to an aspect of the present invention, a temperature control system comprises: a circulation channel which includes a temperature adjustment target and through which a circulation fluid that adjusts a temperature of the temperature adjustment target flows; a temperature adjuster that is arranged in the circulation channel and that adjusts a temperature of the circulation fluid supplied to the temperature adjustment target; a first temperature adjustment unit that is connected to the circulation channel via a first supply channel and that delivers a first fluid having a first temperature; a second temperature adjustment unit that is connected to the circulation channel via a second supply channel and that delivers a second fluid having a second temperature higher than the first temperature; a first valve arranged in the first supply channel; and a second valve arranged in the second supply channel, wherein the second valve is an electromagnetic valve, and closes the second supply channel after opening the second supply channel when a set temperature of the temperature adjustment target is changed from a first set temperature to a second set temperature higher than the first set temperature.

### Advantageous Effects of Invention

According to the present disclosure, a temperature of fluid flowing through a circulation channel is adjusted to a set temperature in a short time.

### BRIEF DESCRIPTION OF DRAWINGS

FIG. 1 is a configuration diagram illustrating a temperature control system according to an embodiment.

FIG. 2 is a block diagram illustrating the temperature control system according to the embodiment.

FIG. 3 is a view schematically illustrating an example of a temperature adjuster according to the embodiment.

FIG. 4 is an enlarged cross-sectional view of a part of a temperature adjustment portion according to the embodiment.

FIG. 5 is a flowchart illustrating a temperature control method according to the embodiment.

FIG. 6 is a view for describing a first valve, a second valve, a third valve, a fourth valve, a fifth valve, a sixth valve, and a ninth valve set to a steady state according to the embodiment.

FIG. 7 is a view for describing the first valve, the second valve, the third valve, the fourth valve, the fifth valve, the sixth valve, and the ninth valve set to a changed state according to the embodiment.

FIG. 8 is a view illustrating a temperature control system of when each of the first valve, the second valve, the third valve, the fourth valve, the fifth valve, the sixth valve, and the ninth valve according to the embodiment is set to the changed state.

FIG. 9 is a timing chart illustrating the temperature control method according to the embodiment.

FIG. 10 is a graph illustrating a detected temperature of circulation fluid in each of a case where an electromagnetic valve is used as the second valve and a case where a three-way valve is used as the second valve according to the embodiment.

FIG. 11 is a configuration diagram illustrating the temperature control system according to the embodiment.

FIG. 12 is a configuration diagram illustrating the temperature control system according to the embodiment.

FIG. 13 is a configuration diagram illustrating the temperature control system according to the embodiment.

### DESCRIPTION OF EMBODIMENTS

In the following, embodiments according to the present disclosure will be described with reference to the drawings. However, the present disclosure is not limited to the embodiments. Components of the embodiments described in the following can be arbitrarily combined. Also, there is a case where a part of the components is not used.

[Temperature Control System]

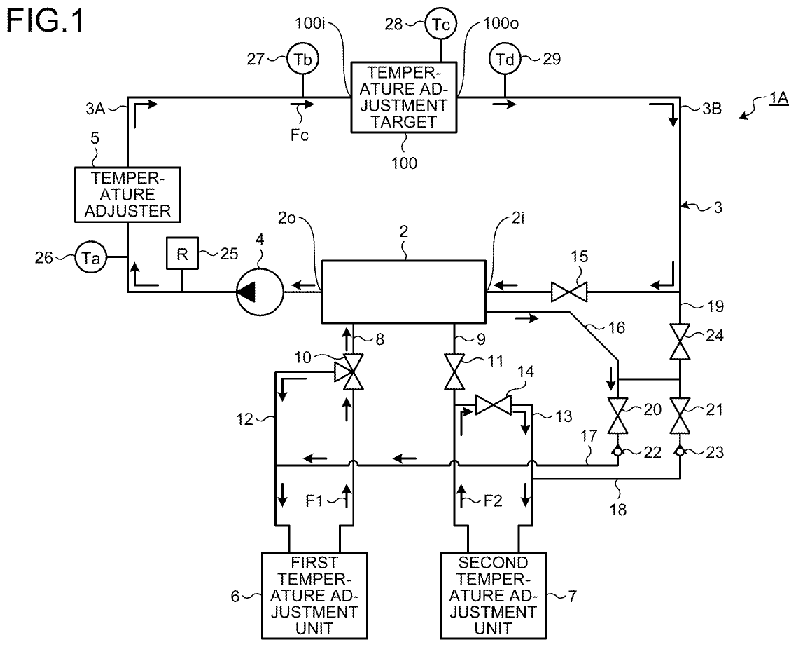

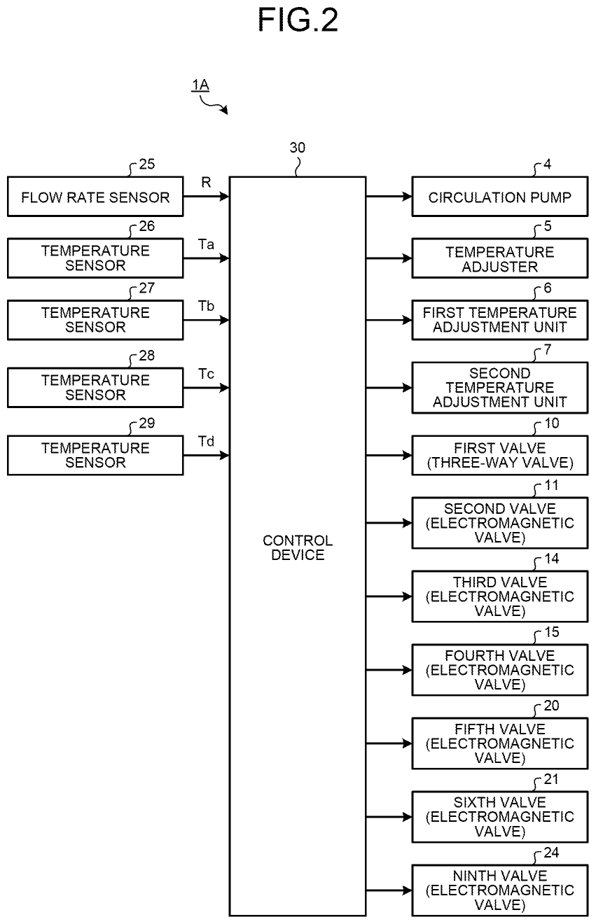

FIG. 1 is a configuration diagram illustrating a temperature control system 1A according to an embodiment. FIG. 2 is a block diagram illustrating the temperature control system 1A according to the embodiment. As illustrated in FIG. 1 and FIG. 2, the temperature control system 1A includes a circulation channel 3 including a temperature adjustment target 100, a circulation pump 4 arranged in the circulation channel 3, a temperature adjuster 5 arranged in the circulation channel 3, a first temperature adjustment unit 6 arranged outside the circulation channel 3, a second temperature adjustment unit 7 arranged outside the circulation channel 3, a first supply channel 8 that connects the circulation channel 3 and the first temperature adjustment unit 6, a second supply channel 9 that connects the circulation channel 3 and the second temperature adjustment unit 7, a first valve arranged in the first supply channel 8, and a second valve 11 arranged in the second supply channel 9.

Furthermore, the temperature control system 1A includes a first return channel 12 that connects the first valve 10 and the first temperature adjustment unit 6, a second return channel 13 that connects the second supply channel 9 and the second temperature adjustment unit 7, a third valve 14 arranged in the second return channel 13, a fourth valve 15 arranged in the circulation channel 3, an overflow channel 16 connected to the circulation channel 3, a first overflow channel 17 that connects the overflow channel 16 and the first temperature adjustment unit 6, a second overflow channel 18 that connects the overflow channel 16 and the second temperature adjustment unit 7, a bypass channel 19 that branches off from the circulation channel 3, a fifth valve 20 arranged in the first overflow channel 17, a sixth valve 21 arranged in the second overflow channel 18, a seventh valve 22 arranged in the first overflow channel 17, an eighth valve 23 arranged in the second overflow channel 18, and a ninth valve 24 arranged in the bypass channel 19.

In addition, the temperature control system 1A includes a flow rate sensor 25 that detects a flow rate R of the circulation fluid Fc flowing through the circulation channel 3, a temperature sensor 26 that detects a temperature Ta of the circulation fluid Fc flowing into the temperature adjuster 5, a temperature sensor 27 that detects a temperature Tb of the circulation fluid Fc flowing into the temperature adjustment target 100, a temperature sensor 28 that detects a temperature Tc of the temperature adjustment target 100, a temperature sensor 29 that detects a temperature Td of the circulation fluid Fc flowing cut from the temperature adjustment target 100, and a control device 30 that controls the temperature control system 1A.

At least a part of a semiconductor manufacturing device is described as an example of the temperature adjustment target 100. In the embodiment, the temperature adjustment target 100 is a wafer holder of a plasma processing device. The wafer holder holds a semiconductor wafer subjected to plasma processing in the plasma processing device. The wafer holder is made of aluminum, for example. The wafer holder includes an electrostatic chuck that holds the semiconductor wafer with electrostatic adsorption force. The electrostatic chuck sucks and holds the semiconductor wafer with Coulomb force when a DC voltage is applied. When a temperature of the wafer holder is controlled, a temperature of the semiconductor wafer held by the wafer holder is adjusted.

The temperature control system 1A controls the temperature of the temperature adjustment target 100 by supplying the circulation fluid Fc to the temperature adjustment target 100. In the embodiment, the circulation fluid Fc is liquid. Note that the circulation fluid Fc may be gas.

The circulation channel 3 includes a tank 2, a supply portion 3A through which the circulation fluid Fc supplied from the tank 2 to the temperature adjustment target 100 flows, and a return portion 3B through which the circulation fluid Fc returned from the temperature adjustment target 100 to the tank 2 flows. The circulation fluid Fc that adjusts the temperature of the temperature adjustment target 100 circulates through the circulation channel 3. The tank 2 houses the circulation fluid Fc. Each of the supply portion 3A and the return portion 3B is a pipeline. The tank 2 functions as a buffer of the circulation fluid Fc in the circulation channel 3. The supply portion 3A connects an outlet 2o of the tank 2 and an inlet 100i of the temperature adjustment target 100. The return portion 3B connects an outlet 100o of the temperature adjustment target 100 and an inlet 2i of the tank 2.

The circulation pump 4 is driven in such a manner that the circulation fluid Fc circulates in the circulation channel 3. The circulation pump 4 is arranged in the supply portion 3A. The circulation pump 4 is controlled by the control device 30. When the circulation pump 4 is driven, the circulation fluid Fc flowing out from the outlet 2o of the tank 2 flows through the supply portion 3A, and then is supplied to the temperature adjustment target 100 via the inlet 100i of the temperature adjustment target 100. The circulation fluid Fc flowing through the temperature adjustment target 100 flows out from the outlet 100o of the temperature adjustment target 100, flows through the return portion 3B, and then flows into the tank 2 via the inlet 2i of the tank 2.

The temperature adjuster 5 adjusts the temperature of the circulation fluid Fc supplied from the tank 2 to the temperature adjustment target 100. The temperature adjuster 5 is arranged in the supply portion 3A between the circulation pump 4 and the temperature adjustment target 100. The temperature adjuster 5 is controlled by the control device 30.

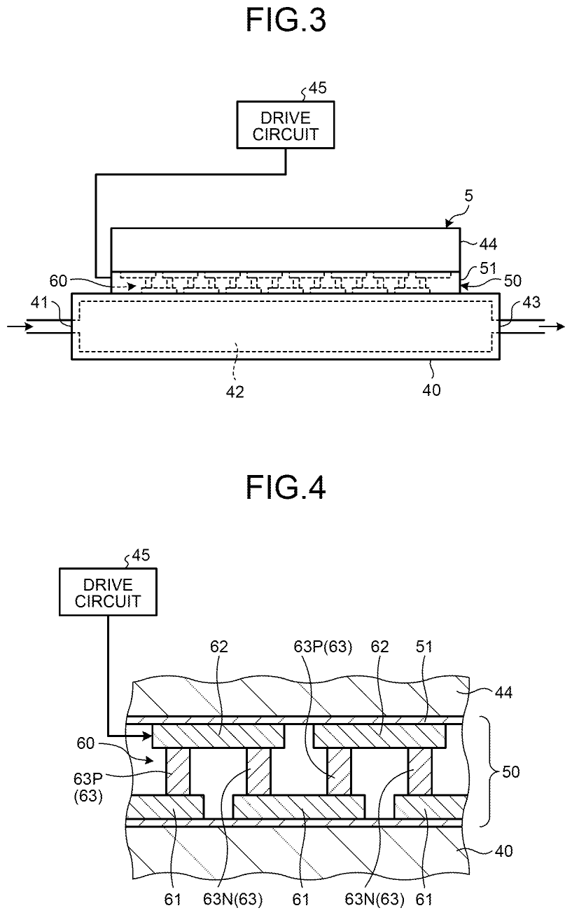

FIG. 3 is a view schematically illustrating an example of the temperature adjuster 5 according to the embodiment. As illustrated in FIG. 3, the temperature adjuster 5 includes a main body member 40 having a temperature adjustment channel 42, a temperature adjustment portion 50 connected to the main body member 40, a heat exchange plate 44 connected to the temperature adjustment portion 50, and a drive circuit 45 that drives the temperature adjustment portion 50. In the embodiment, the temperature adjuster 5 includes a thermoelectric module 60.

The temperature adjustment channel 42 is provided inside the main body member 40. The circulation fluid Fc from the tank 2 flows into the temperature adjustment channel 42 via an inlet 41. The circulation fluid Fc flowing through the temperature adjustment channel 42 flows out from the temperature adjustment channel 42 via an outlet 43. The circulation fluid Fc flowing out of the temperature adjustment channel 42 is supplied to the temperature adjustment target 100.

Via the main body member 40, the temperature adjustment portion 50 adjusts the temperature of the circulation fluid Fc flowing through the temperature adjustment channel 42. The temperature adjustment portion includes the thermoelectric module 60. The temperature adjustment portion 50 adjusts the temperature of the circulation fluid Fc by using the thermoelectric module 60.

The thermoelectric module 60 absorbs heat or generates heat, and adjusts the temperature of the circulation fluid Fc flowing through the temperature adjustment channel 42. The thermoelectric module 60 absorbs heat or generates heat by supply of electric power. The thermoelectric module 60 absorbs heat or generates heat by the Peltier effect.

The heat exchange plate 44 exchanges heat with the temperature adjustment portion 50. The heat exchange plate 44 has an internal channel (not illustrated) through which a temperature adjustment medium flows. The temperature adjustment medium flows into the internal channel of the heat exchange plate 44 after a temperature adjustment by a medium temperature control device (not illustrated). The temperature adjustment medium flows through the internal channel, and takes heat from the heat exchange plate 44 or apply heat to the heat exchange plate 44. The temperature adjustment medium flows out from the internal channel and is returned to a fluid temperature control device.

FIG. 4 is an enlarged cross-sectional view of a part of the temperature adjustment portion 50 according to the embodiment. As illustrated in FIG. 4, the temperature adjustment portion 50 includes a plurality of thermoelectric modules 60 and a case 51 that houses the plurality of thermoelectric modules 60. One end surface of the case 51 is connected to the main body member 40. The other end surface of the case 51 is connected to the heat exchange plate 44.

The thermoelectric module 60 includes a first electrode 61, a second electrode 62, and a thermoelectric semiconductor element 63. The thermoelectric semiconductor element 63 includes p-type thermoelectric semiconductor element 63P and an n-type thermoelectric semiconductor element 63N. The first electrode 61 is connected to each of the p-type thermoelectric semiconductor element 63P and the n-type thermoelectric semiconductor element 63N. The second electrode 62 is connected to each of the p-type thermoelectric semiconductor element 63P and the n-type thermoelectric semiconductor element 63N. The first electrode 61 is adjacent to the main body member 40. The second electrode 62 is adjacent to the heat exchange plate 44. Each of one end surface of the p-type thermoelectric semiconductor element 63P and one end surface of the n-type thermoelectric semiconductor element 63N is connected to the first electrode 61. Each of the other end surface of the p-type thermoelectric semiconductor element 63P and the other end surface of the n-type thermoelectric semiconductor element 63N is connected to the second electrode 62.

The thermoelectric module 60 absorbs heat or generates heat by the Peltier effect. The drive circuit 45 supplies, to the thermoelectric module 60, electric power to make the thermoelectric module 60 to absorb heat or generate heat. The drive circuit 45 applies a potential difference between the first electrode 61 and the second electrode 62. When the potential difference is applied between the first electrode 61 and the second electrode 62, charges move in the thermoelectric semiconductor element 63. Heat moves in the thermoelectric semiconductor element 63 by the movement of the charges. Thus, the thermoelectric module 60 absorbs heat or generates heat. For example, when the potential difference is applied between the first electrode 61 and the second electrode 62 in such a manner that the first electrode 61 generates heat and the second electrode 62 absorbs heat, the circulation fluid Fc flowing through the temperature adjustment channel 42 is heated. When the potential difference is applied between the first electrode 61 and the second electrode 62 in such a manner that the first electrode 61 absorbs heat and the second electrode 62 generates heat, the circulation fluid Fc flowing through the temperature adjustment channel 42 is cooled.

The drive circuit 45 applies electric power (potential difference) to the thermoelectric module 60. The drive circuit 45 is controlled by the control device 30. The amount of heat absorbed or generated by the thermoelectric module 60 is adjusted by an adjustment of the electric power applied to the thermoelectric module 60. By the adjustment of the amount of heat absorbed or generated by the thermoelectric module 60, the temperature of the circulation fluid Fc flowing through the temperature adjustment channel 42 is adjusted.

The first temperature adjustment unit 6 delivers a first fluid F1 having a first temperature 11. The first temperature adjustment unit 6 is connected to the circulation channel 3 via the first supply channel 8. In the embodiment, the first supply channel 8 is connected to the tank 2. The first temperature adjustment unit 6 is connected to the tank 2 via the first supply channel 8. The first temperature adjustment unit 6 delivers the first fluid F1 to the first supply channel 8.

The first temperature adjustment unit 6 is controlled by the control device 30. The first temperature adjustment unit 6 includes a first tank, a first temperature adjuster, and a first pump that delivers the first fluid F1. The first temperature adjuster includes a heat exchanger. The first temperature adjuster adjusts the temperature of the first fluid F1 to a first temperature T1. The first fluid F1 adjusted to the first temperature T1 is stored in the first tank. For example, the first temperature T1 is 5° C.

The second temperature adjustment unit 7 delivers a second fluid F2 having a second temperature T2 higher than the first temperature T1. The second temperature adjustment unit 7 is connected to the circulation channel 3 via the second supply channel 9. In the embodiment, in the embodiment, the second supply channel 9 is connected to the tank 2. The second temperature adjustment unit 7 is connected to the tank 2 via the second supply channel 9. The second temperature adjustment unit 7 delivers the second fluid F2 to the second supply channel 9.

The second temperature adjustment unit 7 is controlled by the control device 30. The second temperature adjustment unit 7 includes a second tank, a second temperature adjuster, and a second pump that delivers the second fluid F2. The second temperature adjuster includes a heat exchanger. The second temperature adjuster adjusts the temperature of the second fluid F2 to the second temperature T2. The second fluid F2 adjusted to the second temperature T2 is stored in the second tank. For example, the second temperature T2 is 85° C.

The first supply channel 8 connects the first temperature adjustment unit 6 and the tank 2. The first fluid F1 delivered from the first temperature adjustment unit 6 flows through the first supply channel 8, and then is supplied to the tank 2.

The second supply channel 9 connects the second temperature adjustment unit 7 and the tank 2. The second fluid F2 delivered from the second temperature adjustment unit 7 flows through the second supply channel 9, and then is supplied to the tank 2.

The first valve 10 is arranged in the first supply channel 8. The first valve 10 is a three-way valve. The first valve 10 is a proportional control valve. The first valve 10 is controlled by the control device 30. The first valve 10 can adjust the flow rate of the first fluid F1 supplied from the first temperature adjustment unit 6 to the circulation channel 3.

The second valve 11 is arranged in the second supply channel 9. The second valve 11 is an electromagnetic valve. The second valve is an on-off valve (on-off valve). The second valve 11 is controlled by the control device 30. The second valve 11 can close and open the second supply channel 9. When the second supply channel 9 is closed, the second fluid F2 is not supplied from the second temperature adjustment unit 7 to the tank 2. When the second supply channel 9 is opened, the second fluid F2 is supplied from the second temperature adjustment unit 7 to the tank 2.

The first return channel 12 connects the first valve 10 and the first temperature adjustment unit 6. The first valve 10 is can be operated in such a manner that at least a part of the first fluid F1 delivered from the first temperature adjustment unit 6 to the first supply channel 8 is returned to the first temperature adjustment unit 6 via the first return channel 12.

As illustrated in FIG. 1, when the first valve 10 opens the first supply channel 8 at a first opening degree and opens the first return channel 12 at a second opening degree, a part of the first fluid F1 delivered from the first temperature adjustment unit 6 to the first supply channel 8 is supplied to the tank 2 via the first valve 10 and the first supply channel 8. A part of the first fluid F1 delivered from the first temperature adjustment unit 6 to the first supply channel 8 is returned to the first temperature adjustment unit 6 via the first valve 10 and the first return channel 12. A part of the first fluid F1 delivered from the first temperature adjustment unit 6 to the first supply channel 8 circulates in a circulation channel including the first temperature adjustment unit 6, the first supply channel 8, the first valve 10, and the first return channel 12.

When the first valve 10 closes the first return channel 12 and opens the first supply channel 8, the entire first fluid F1 delivered from the first temperature adjustment unit 6 to the first supply channel 8 is supplied to the tank 2 via the first valve 10 and the first supply channel 8.

When the first valve 10 closes the first supply channel 8 and opens the first return channel 12, the entire first fluid F1 delivered from the first temperature adjustment unit 6 to the first supply channel 8 is returned to the first temperature adjustment unit 6 via the first valve 10 and the first return channel 12. The first fluid F1 delivered from the first temperature adjustment unit 6 to the first supply channel 8 circulates in a circulation channel including the first temperature adjustment unit 6, a part of the first supply channel 8, the first valve 10, and the first return channel 12.

The second return channel 13 connects the second supply channel 9 between the second valve 11 and the second temperature adjustment unit 7 to the second temperature adjustment unit 7.

The third valve 14 is arranged in the second return channel 13. The third valve 14 is an electromagnetic valve. The third valve 14 is an on-off valve (on-off valve). The third valve 14 is controlled by the control device 30. The third valve 14 can close and open the second return channel 13. When the second return channel 13 is closed, the second fluid F2 delivered from the second temperature adjustment unit 7 is not returned to the second temperature adjustment unit 7.

The third valve 14 closes the second return channel 13 when the second valve 11 opens the second supply channel 9. The third valve 14 opens the second return channel 13 in such a manner that the second fluid F2 delivered from the second temperature adjustment unit 7 to the second supply channel 9 is returned to the second temperature adjustment unit 7 via the second return channel 13 when the second valve 11 closes the second supply channel 9.

As illustrated in FIG. 1, when the second valve 11 closes the second supply channel 9 and the third valve 14 opens the second return channel 13, the entire second fluid F2 delivered from the second temperature adjustment unit 7 to the second supply channel 9 is returned to the second temperature adjustment unit 7 via the third valve 14 and the second return channel 13. The second fluid F2 delivered from the second temperature adjustment unit 7 to the second supply channel 9 circulates in a circulation channel including the second temperature adjustment unit 7, the second supply channel 9, the third valve 14, and the second return channel 13.

When the third valve 14 closes the second return channel 13 and the second valve 11 opens the second supply channel 9, the entire second fluid F2 delivered from the second temperature adjustment unit 7 to the second supply channel 9 is supplied to the tank 2 via the second valve 11 and the second supply channel 9.

When the second fluid F2 is supplied from the second temperature adjustment unit 7 to the tank 2, the first fluid F1 is not supplied from the first temperature adjustment unit 6 to the tank 2. That is, when the second valve 11 opens the second supply channel 9, the first valve 10 closes the first supply channel 8.

When the first fluid F1 is supplied from the first temperature adjustment unit 6 to the tank 2, the second fluid F2 is not supplied from the second temperature adjustment unit 7 to the tank 2. That is, when the first valve 10 opens the first supply channel 8, the second valve 11 closes the second supply channel 9.

The circulation fluid Fc and at least one of the first fluid F1 and the second fluid F2 supplied to the tank 2 are mixed in the tank 2. When the first fluid F1 is supplied from the first temperature adjustment unit 6 to the tank 2, the circulation fluid Fc and the first fluid F1 are mixed in the tank 2. When the second fluid F2 is supplied from the second temperature adjustment unit 7 to the tank 2, the circulation fluid Fc and the second fluid F2 are mixed in the tank 2.

The fourth valve 15 is arranged in the circulation channel 3. In the embodiment, the fourth valve is arranged in the return portion 3B of the circulation channel 3 between the outlet 100o of the temperature adjustment target 100 and the inlet 2i of the tank 2. The fourth valve 15 is an electromagnetic valve. The fourth valve 15 is an on-off valve (on-off valve). The fourth valve 15 is controlled by the control device 30. The fourth valve 15 can close and open the return portion 3B of the circulation channel 3. When the return portion 3B is closed, the circulation fluid Fc delivered from the temperature adjustment target 100 is not returned to the tank 2. When the return portion 3B is opened, the circulation fluid Fc delivered from the temperature adjustment target 100 is returned to the tank 2.

The fourth valve 15 closes the circulation channel 3 when the second valve 11 opens the second supply channel 9. The fourth valve 15 opens the circulation channel 3 when the second valve 11 closes the second supply channel 9. That is, when the second fluid F2 is supplied from the second temperature adjustment unit 7 to the tank 2, the circulation fluid Fc is not returned from the temperature adjustment target 100 to the tank 2. When the second fluid F2 is not supplied from the second temperature adjustment unit 7 to the tank 2, the circulation fluid Fc is returned from the temperature adjustment target 100 to the tank 2.

The overflow channel 16 is connected to the tank 2. The overflow channel 16 is connected to the tank 2 in such a manner as to branch off from the circulation channel 3.

The first overflow channel 17 connects the circulation channel 3 and the first temperature adjustment unit 6. In the embodiment, one end portion of the first overflow channel 17 is connected to the overflow channel 16, and is connected to the tank 2 via the overflow channel 16. The other end portion of the first overflow channel 17 is connected to the first return channel 12, and is connected to the first temperature adjustment unit 6 via the first return channel 12.

The second overflow channel 18 connects the circulation channel 3 and the second temperature adjustment unit 7. In the embodiment, one end portion of the second overflow channel 18 is connected to the overflow channel 16, and is connected to the tank 2 via the overflow channel 16. The other end portion of the second overflow channel 18 is connected to the second return channel 13, and is connected to the second temperature adjustment unit 7 via the second return channel 13.

The bypass channel 19 connects the return portion 3B of the circulation channel 3 to each of the first overflow channel 17 and the second overflow channel 18.

The fifth valve 20 is arranged in the first overflow channel 17. The fifth valve 20 is an electromagnetic valve. The fifth valve 20 is an on-off valve (on-off valve). The fifth valve 20 is controlled by the control device 30. The fifth valve 20 can close and open the first overflow channel 17. When the first overflow channel 17 is closed, the circulation fluid Fc is not supplied from the tank 2 to the first temperature adjustment unit 6. When the first overflow channel 17 is opened, the circulation fluid Fc is supplied from the tank 2 to the first temperature adjustment unit 6.

The fifth valve 20 closes the first overflow channel 17 when the second valve 11 opens the second supply channel 9, and opens the first overflow channel 17 when the second valve 11 closes the second supply channel 9. That is, when the second fluid F2 is supplied from the second temperature adjustment unit 7 to the tank 2, the circulation fluid Fc is not supplied from the tank 2 to the first temperature adjustment unit 6. When the second fluid F2 is not supplied from the second temperature adjustment unit 7 to the tank 2, the circulation fluid Fc is supplied from the tank 2 to the first temperature adjustment unit 6.

The sixth valve 21 is arranged in the second overflow channel 18. The sixth valve 21 is an electromagnetic valve. The sixth valve 21 is an on-off valve (on-off valve). The sixth valve 21 is controlled by the control device 30. The sixth valve 21 can close and open the second overflow channel 18. When the second overflow channel 18 is closed, the circulation fluid Fc is not supplied from the tank 2 to the second temperature adjustment unit 7. When the second overflow channel 18 is opened, the circulation fluid Fc is supplied from the tank 2 to the second temperature adjustment unit 7.

The sixth valve 21 opens the second overflow channel 18 when the second valve 11 opens the second supply channel 9, and closes the second overflow channel 18 when the second valve 11 closes the second supply channel 9. That is, when the second fluid F2 is supplied from the second temperature adjustment unit 7 to the tank 2, the circulation fluid Fc is supplied from the tank 2 to the second temperature adjustment unit 7. When the second fluid F2 is not supplied from the second temperature adjustment unit 7 to the tank 2, the circulation fluid Fc is not supplied from the tank 2 to the second temperature adjustment unit 7.

The seventh valve 22 is arranged between the fifth valve 20 and the first return channel 12 in the first overflow channel 17. The seventh valve 22 is a check valve that controls supply of the first fluid F1 from the first temperature adjustment unit 6 to the tank 2 via the first overflow channel 17.

The eighth valve 23 is arranged between the sixth valve 21 and the second return channel 13 in the second overflow channel 18. The eighth valve 23 is a check valve that controls supply of the second fluid F2 from the second temperature adjustment unit 7 to the tank 2 via the second overflow channel 18.

The ninth valve 24 is arranged in the bypass channel 19. The ninth valve 24 is an electromagnetic valve. The ninth valve 24 is an on-off valve (on-off valve). The ninth valve 24 is controlled by the control device 30. The ninth valve 24 can close and open the bypass channel 19. When the bypass channel 19 is closed, the circulation fluid Fc is not supplied from the return portion 3B to each of the first overflow channel 17 and the second overflow channel 18. When the bypass channel 19 is opened, the circulation fluid Fc is supplied from the return portion 3B to each of the first overflow channel 17 and the second overflow channel 18. When the first overflow channel 17 is opened in a state in which the bypass channel 19 is opened, the circulation fluid Fc is supplied from the return portion 3B to the first temperature adjustment unit 6. When the second overflow channel 18 is opened in a state in which the bypass channel 19 is opened, the circulation fluid Fc is supplied from the return portion 3B to the second temperature adjustment unit 7.

The ninth valve 24 opens the bypass channel 19 when the second valve 11 opens the second supply channel 9, and closes the bypass channel 19 when the second valve 11 closes the second supply channel 9.

The flow rate sensor 25 is arranged in the supply portion 3A between the circulation pump 4 and the temperature adjuster 5. The flow rate sensor 25 detects the flow rate R of the circulation fluid Fc that is after flowing out of the tank 2 and before flowing into the temperature adjuster 5.

The temperature sensor 26 is arranged in the supply portion 3A between the circulation pump 4 and the temperature adjuster 5. The temperature sensor 26 detects the temperature Ta of the circulation fluid Fc that is after flowing out of the tank 2 and before flowing into the temperature adjuster 5.

The temperature sensor 27 is arranged in the supply portion 3A between the temperature adjuster 5 and the temperature adjustment target 100. The temperature sensor 27 detects the temperature Tb of the circulation fluid Fc the temperature of which is adjusted by the temperature adjuster 5 and which is before flowing into the temperature adjustment target 100.

The temperature sensor 28 is arranged on the temperature adjustment target 100. The temperature sensor 28 detects the temperature Tc of the temperature adjustment target 100. Note that the temperature sensor 28 may detect the temperature of the circulation fluid Fe flowing through the temperature adjustment target 100.

The temperature sensor 29 is arranged in the return portion 3B between the temperature adjustment target 100 and the fourth valve 15. The temperature sensor 29 detects the temperature Td of the circulation fluid Fc that is after flowing out of the temperature adjustment target 100 and before flowing into the tank 2.

The control device 30 includes a computer system. The control device 30 includes a processor, a main memory, a storage, and an interface. Examples of the processor include a central processing unit (CPU) and a micro processing unit (MPU). Examples of the main memory include a nonvolatile memory and a volatile memory. Examples of the nonvolatile memory include a read only memory (ROM). Examples of the volatile memory include a random access memory (RAM). Examples of the storage include a magnetic disk, a magneto-optical disk, and a semiconductor memory. Examples of the interface include an input/output circuit and a communication circuit.

The control device 30 controls each of the temperature adjuster 5, the first valve 10, and the second valve 11 in such a manner that the temperature of the temperature adjustment target 100 becomes the set temperature SV. The set temperature SV of the temperature adjustment target 100 means a target temperature of the temperature adjustment target 100.

Furthermore, the control device 30 controls each of the third valve 14, the fourth valve 15, the fifth valve the sixth valve 21, and the ninth valve 24 in accordance with the state of the first valve 10 and the state of the second valve 11.

The control device 30 controls each of the temperature adjuster 5, the first valve 10, and the second valve 11 on the basis of, for example, detection data of the temperature sensor 27, detection data of the temperature sensor 28, or detection data of the temperature sensor 29. In the embodiment, in order to simplify the description, it is assumed that the control device 30 controls each of the temperature adjuster 5, the first valve 10, and the second valve 11 on the basis of the detection data of the temperature sensor 29. Furthermore, in the following description, a temperature of the circulation fluid Fc which temperature is detected by the temperature sensor 29 is appropriately referred to as a detected temperature PV of the circulation fluid Fc.

In the embodiment, when the set temperature SV of the temperature adjustment target 100 is changed from a first set temperature SV1 to a second set temperature SVh higher than the first set temperature SV1, the second valve 11 opens the second supply channel 9 and then closes the second supply channel 9. Since the second valve 11 is the electromagnetic valve, it is possible to quickly open the second supply channel 9 and quickly supply the second fluid F2 to the tank 2. In addition, since the second valve 11 is the electromagnetic valve, it is possible to quickly close the second supply channel 9 and quickly stop the supply of the second fluid F2 to the tank 2. That is, an appropriate amount of the second fluid F2 is quickly supplied to the circulation channel 3 by the opening and closing operation of the second valve 11. Since the appropriate amount of the second fluid F2 is quickly supplied to the circulation channel 3, the temperature of the circulation fluid Fc is quickly adjusted.

In the embodiment, when the set temperature SV is changed from the first set temperature SV1 to the second set temperature SVh, the opening and closing operation of the second valve 11 is performed only once. The opening and closing operation of the second valve 11 means operation of opening and then closing the second supply channel 9. Since the opening and closing operation of the second valve 11 is not performed many times, deterioration of the second valve 11 is controlled.

The temperature adjuster 5 adjusts the temperature of the circulation fluid Fc in such a manner that the temperature of the circulation fluid Fc supplied to the temperature adjustment target 100 becomes the second set temperature SVh when the second valve 11 closes the second supply channel 9. Since the temperature adjuster 5 includes the thermoelectric module 60, the temperature of the circulation fluid Fc can be adjusted with high accuracy.

In addition, the first valve 10 adjusts the flow rate of the first fluid F1 supplied to the circulation channel 3 in such a manner that the temperature of the circulation fluid Fc supplied to the temperature adjustment target 100 becomes the second set temperature SVh when the second valve 11 closes the second supply channel 9. Since the first valve 10 is the proportional control valve, the flow rate of the first fluid F1 supplied to the circulation channel 3 can be adjusted with high accuracy. Since the flow rate of the first fluid F1 supplied to the circulation channel 3 is adjusted with high accuracy, the temperature of the circulation fluid Fc is adjusted with high accuracy.

That is, in the embodiment, when the set temperature SV of the temperature adjustment target 100 is changed from the first set temperature SV1 to the second set temperature SVh, the opening and closing operation of the second valve 11 is performed in such a manner that a difference between the temperature of the circulation fluid Fc and the second set temperature SVh becomes small in a short time. After the temperature of the circulation fluid Fc is roughly adjusted by the opening and closing operation of the second valve 11, the temperature of the circulation fluid Fc is adjusted with high accuracy by one or both of the temperature adjuster 5 and the first fluid F1 the flow rate of which is adjusted with high accuracy.

[Control Method]

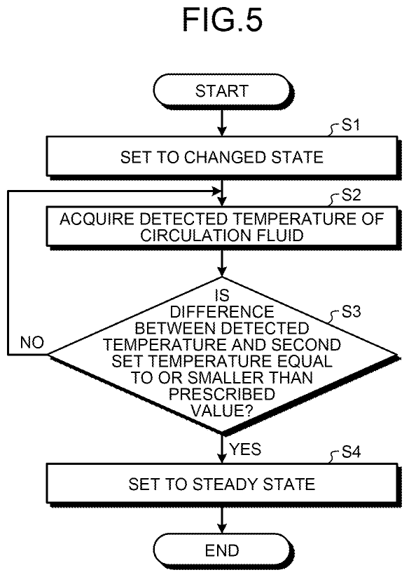

FIG. 5 is a flowchart illustrating a temperature control method according to the embodiment. A temperature control method of the temperature adjustment target 100 of when the set temperature SV of the temperature adjustment target 100 is changed from the first set temperature SV1 to the second set temperature SVh higher than the first set temperature SV1 will be described with reference to FIG. 5.

In a case where the temperature adjustment target 100 is the wafer holder of the plasma processing device, the set temperature SV of the wafer holder may be changed in a state in which the wafer is held in the wafer holder. That is, the set temperature SV of the wafer holder may be set to the first set temperature SV1 or the second set temperature SVh on the basis of contents of the plasma processing. For example, the first set temperature SV1 is ° C., and the second set temperature SVh is 60° C.

When the set temperature SV of the temperature adjustment target 100 is maintained at the first set temperature SV1, each of the first valve 10, the second valve 11, the third valve 14, the fourth valve 15, the fifth valve 20, the sixth valve 21, and the ninth valve 24 is set to the steady state.

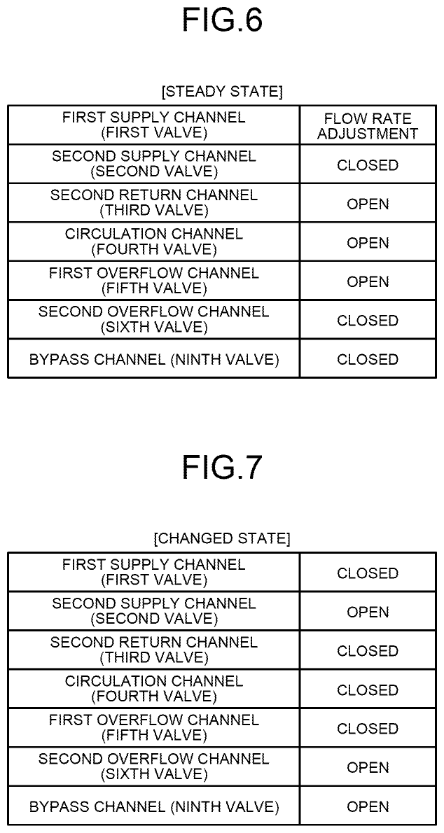

FIG. 6 is a view for describing the first valve the second valve 11, the third valve 14, the fourth valve 15, the fifth valve 20, the sixth valve 21, and the ninth valve 24 set to the steady state according to the embodiment. In addition, FIG. 1 is a view illustrating the temperature control system 1A of when each of the first valve 10, the second valve 11, the third valve 14, the fourth valve 15, the fifth valve 20, the sixth valve 21, and the ninth valve 24 is set to the steady state.

As illustrated in FIG. 1 and FIG. 6, the steady state is a state in which the first valve 10 adjusts the flow rate of the first fluid F1 supplied to the circulation channel 3, the second valve 11 closes the second supply channel 9, the third valve 14 opens the second return channel 13, the fourth valve 15 opens the circulation channel 3, the fifth valve 20 opens the first overflow channel 17, the sixth valve 21 closes the second overflow channel 18, and the ninth valve 24 closes the bypass channel 19.

The control device 30 controls the fourth valve 15 in such a manner that the circulation channel 3 is opened when the set temperature SV of the temperature adjustment target 100 is maintained at the first set temperature SV1. The control device 30 controls the temperature adjuster 5 in such a manner that the temperature adjustment target 100 reaches the first set temperature SV1 in a state in which the circulation fluid Fc circulates in the circulation channel 3. In addition, the control device 30 controls the first valve 10 and adjusts the flow rate of the first fluid F1 supplied from the first temperature adjustment unit 6 to the circulation channel 3 in such a manner that the temperature adjustment target 100 reaches the first set temperature SV1 in a state in which the circulation fluid Fc circulates in the circulation channel 3. The control device 30 controls the temperature adjuster 5 and the first valve 10 on the basis of the detected temperature PV of the circulation fluid Fc.

As illustrated in FIG. 1, a part of the first fluid F1 delivered from the first temperature adjustment unit 6 to the first supply channel 8 is supplied to the tank 2. A part of the first fluid F1 delivered from the first temperature adjustment unit 6 to the first supply channel 8 is returned to the first temperature adjustment unit 6 via the first return channel 12.

In addition, in a case where the first fluid F1 is supplied from the first temperature adjustment unit 6 to the circulation channel 3, the control device 30 controls the fifth valve 20 in such a manner that the first overflow channel 17 is opened, controls the sixth valve 21 in such a manner that the second overflow channel 18 is closed, and controls the ninth valve 24 in such a manner that the bypass channel 19 is closed. When the first fluid F1 is supplied to the circulation channel 3, the amount of the circulation fluid Fc flowing through the circulation channel 3 increases. When the first overflow channel 17 is opened, the surplus circulation fluid Fc in the circulation channel 3 is supplied to the first temperature adjustment unit 6 via the first overflow channel 17.

In addition, when the set temperature SV is maintained at the first set temperature SV1, the control device 30 controls the second valve 11 in such a manner that the second supply channel 9 is closed, and controls the third valve 14 in such a manner that the second return channel 13 is opened. When the second supply channel 9 is closed and the second return channel 13 is opened, the entire second fluid F2 delivered from the second temperature adjustment unit 7 is returned to the second temperature adjustment unit 7 as illustrated in FIG. 1.

When the set temperature SV of the temperature adjustment target 100 is changed from the first set temperature SV1 to the second set temperature SVh higher than the first set temperature SV1, each of the first valve the second valve 11, the third valve 14, the fourth valve 15, the fifth valve 20, the sixth valve 21, and the ninth valve 24 is set to the changed state (Step S1).

Note that in a case where the set temperature SV is changed from the first set temperature SV1 to the second set temperature SVh, the plasma processing is stopped.

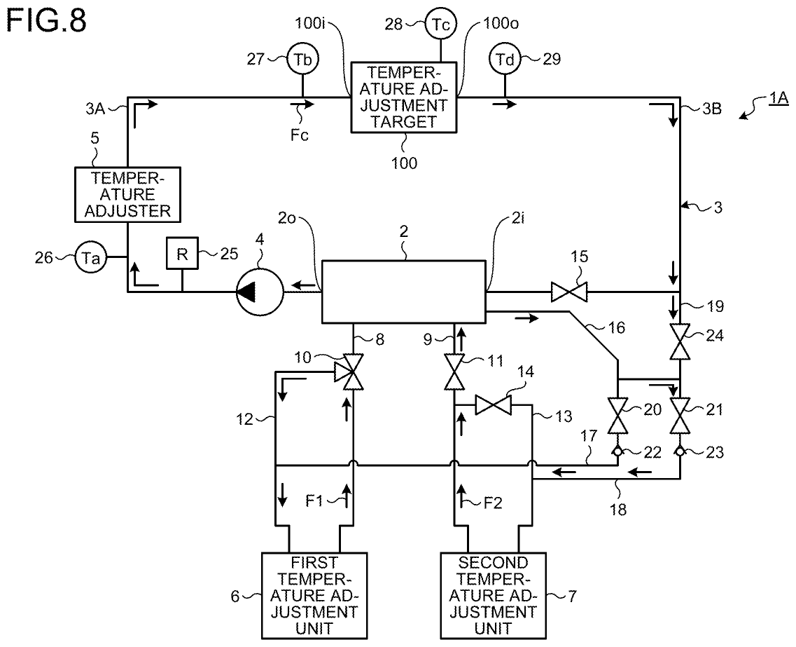

FIG. 7 is a view for describing the first valve the second valve 11, the third valve 14, the fourth valve 15, the fifth valve 20, the sixth valve 21, and the ninth valve 24 set to the changed state according to the embodiment. FIG. 8 is a view illustrating the temperature control system 1A of when each of the first valve 10, the second valve 11, the third valve 14, the fourth valve 15, the fifth valve 20, the sixth valve 21, and the ninth valve 24 according to the embodiment is set to the changed state.

As illustrated in FIG. 7 and FIG. 8, the changed state is a state in which the first valve 10 closes the first supply channel 8, the second valve 11 opens the second supply channel 9, the third valve 14 closes the second return channel 13, the fourth valve 15 closes the circulation channel 3, the fifth valve 20 closes the first overflow channel 17, the sixth valve 21 opens the second overflow channel 18, and the ninth valve 24 opens the bypass channel 19.

The control device 30 controls the second valve 11 in such a manner that the second supply channel 9 is opened when the set temperature SV is changed from the first set temperature SV1 to the second set temperature SVh. In addition, the control device 30 controls the third valve 14 in such a manner that the second return channel 13 is closed when the set temperature SV is changed from the first set temperature SV1 to the second set temperature SVh. When the second supply channel 9 is opened and the second return channel 13 is closed, the entire second fluid F2 delivered from the second temperature adjustment unit 7 to the second supply channel 9 is supplied to the tank 2 as illustrated in FIG. 8.

Furthermore, the control device 30 controls the first valve 10 in such a manner that the first supply channel 8 is closed when the set temperature SV is changed from the first set temperature SV1 to the second set temperature SVh. When the first supply channel 8 is closed by the first valve 10, the entire first fluid F1 delivered from the first temperature adjustment unit 6 to the first supply channel 8 is returned to the first temperature adjustment unit 6 via the first return channel 12.

Furthermore, the control device 30 controls the fourth valve 15 in such a manner that the return portion 3B of the circulation channel 3 is closed when the set temperature SV is changed from the first set temperature SV1 to the second set temperature SVh.

Furthermore, in a case where the second fluid F2 is supplied from the second temperature adjustment unit 7 to the circulation channel 3, the control device 30 controls the sixth valve 21 in such a manner that the second overflow channel 18 is opened, and controls the fifth valve 20 in such a manner that the first overflow channel 17 is closed. When the second fluid F2 is supplied to the circulation channel 3, the amount of the circulation fluid Fc flowing through the circulation channel 3 increases. When the second overflow channel 18 is opened, the surplus circulation fluid Fc in the circulation channel 3 is supplied to the second temperature adjustment unit 7 via the second overflow channel 18.

In addition, in a case where the return portion 3B of the circulation channel 3 is closed by the fourth valve 15, the control device 30 controls the ninth valve 24 in such a manner that the bypass channel 19 is opened. When the bypass channel 19 is opened, the circulation fluid Fc flowing out from the outlet 100o of the temperature adjustment target 100 is supplied to the second temperature adjustment unit 7 via the bypass channel 19 and the second overflow channel 18.

After setting each of the first valve 10, the second valve 11, the third valve 14, the fourth valve 15, the fifth valve 20, the sixth valve 21, and the ninth valve 24 to the changed state, the control device 30 acquires the detected temperature PV of the circulation fluid Fc from the temperature sensor 29 (Step S2).

The control device 30 determines whether the difference between the detected temperature PV of the circulation fluid Fc acquired in Step S2 and the second set temperature SVh is equal to or smaller than a prescribed value γ (Step S3).

The prescribed value γ is a predetermined value and is stored in the control device 30.

In Step S3, in a case where it is determined that the difference between the detected temperature PV of the circulation fluid Fc and the second set temperature SVh is not equal to or smaller than the prescribed value γ (Step S3: No), the control device 30 maintains each of the third valve 14, the fourth valve 15, the fifth valve 20, the sixth valve 21, and the ninth valve 24 in the changed state until the difference between the detected temperature PV of the circulation fluid Fc and the second set temperature SVh becomes equal to or smaller than the prescribed value γ, and performs the processing of Step S2 and Step S3.

In a case where it is determined in Step S3 that the difference between the detected temperature PV of the circulation fluid Fc and the second set temperature SVh is equal to or smaller than the prescribed value γ (Step S3: Yes), the control device 30 sets each of the first valve the second valve 11, the third valve 14, the fourth valve 15, the fifth valve 20, the sixth valve 21, and the ninth valve 24 to the steady state (Step S4).

In such a manner, after opening the second supply channel 9 in Step S1, the second valve 11 closes the second supply channel 9 when the difference between the detected temperature PV of the circulation fluid Fc and the second set temperature SVh becomes equal to or smaller than the prescribed value γ.

Note that the second valve 11 may close the second supply channel 9 when a prescribed time elapses after the set temperature SV is changed to the second set temperature SVh after the second supply channel 9 is opened in Step S1.

As described with reference to FIG. 1 and FIG. 6, the steady state is a state in which the first valve 10 adjusts the flow rate of the first fluid F1 supplied to the circulation channel 3, the second valve 11 closes the second supply channel 9, the third valve 14 opens the second return channel 13, the fourth valve 15 opens the circulation channel 3, the fifth valve 20 opens the first overflow channel 17, the sixth valve 21 closes the second overflow channel 18, and the ninth valve 24 closes the bypass channel 19.

When the return portion 3B of the circulation channel 3 is opened by the fourth valve 15, the circulation fluid Fc circulates through the circulation channel 3.

The control device 30 controls the temperature adjuster 5 in such a manner that the temperature adjustment target 100 reaches the second set temperature SVh in a state in which the circulation fluid Fc circulates in the circulation channel 3. In addition, the control device 30 controls the first valve 10 and adjusts the flow rate of the first fluid F1 supplied from the first temperature adjustment unit 6 to the circulation channel 3 in such a manner that the temperature adjustment target 100 reaches the second set temperature SVh in a state in which the circulation fluid Fc circulates in the circulation channel 3. The control device 30 controls the temperature adjuster and the first valve 10 on the basis of the detected temperature PV of the circulation fluid Fc.

As illustrated in FIG. 1, a part of the first fluid F1 delivered from the first temperature adjustment unit 6 to the first supply channel 8 is supplied to the tank 2. A part of the first fluid F1 delivered from the first temperature adjustment unit 6 to the first supply channel 8 is returned to the first temperature adjustment unit 6 via the first return channel 12. The second fluid F2 delivered from the second temperature adjustment unit 7 is returned to the second temperature adjustment unit 7.

Note that when the difference between the detected temperature PV of the circulation fluid Fc and the second set temperature SVh becomes equal to or smaller than a predetermined threshold 6, the plasma processing is resumed.

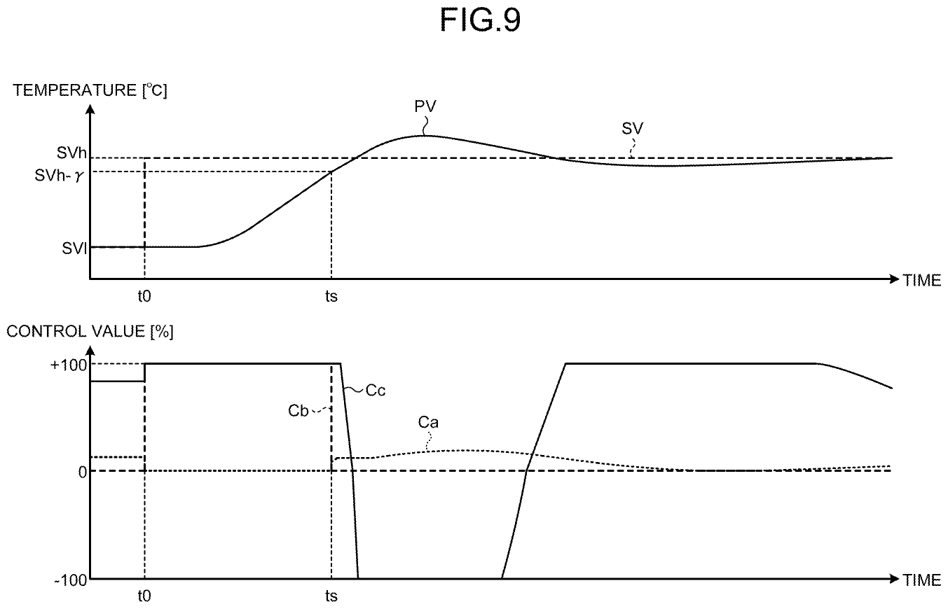

FIG. 9 is a timing chart illustrating the temperature control method according to the embodiment. In FIG. 9, a time point t0 is a time point at which the set temperature SV of the temperature adjustment target 100 is changed from the first set temperature SV1 to the second set temperature SVh. In FIG. 9, a horizontal axis represents elapsed time from the time point t0, a vertical axis of the first graph represents temperature, and a vertical axis of the second graph represents a control value of a control signal output from the control device 30 to each of the first valve 10, the second valve 11, and the temperature adjuster 5.

In the first graph, a line PV indicates the detected temperature PV of the circulation fluid Fc, and a line SV indicates the set temperature SV of the temperature adjustment target 100.

In the second graph, a line Ca indicates a control value Ca of the control signal output to the first valve 10, a line Cb indicates a control value Cb of the control signal output to the second valve 11, and a line Cc indicates a control value Cc of the control signal output to the temperature adjuster 5.

As illustrated in FIG. 9, at the time point t0, the control device 30 outputs the control signal to the first valve 10 in such a manner that the first supply channel 8 changes from a state of being opened at a predetermined opening degree to a closed state. At the time point t0, the control device 30 outputs the control signal to the second valve 11 in such a manner that the second supply channel 9 changes from a closed state to an open state. The control device 30 outputs the control signal to the temperature adjuster 5 in such a manner as to have the highest temperature in an adjustable temperature range of the temperature adjuster 5. As a result, the detected temperature PV of the circulation fluid Fc rapidly rises from the first set temperature SV1. The difference between the detected temperature PV and the second set temperature SVh decreases in a short time.

When the difference between the detected temperature PV of the circulation fluid Fc and the second set temperature SVh becomes equal to or smaller than the prescribed value γ after the second valve 11 opens the second supply channel 9, the control device 30 outputs the control signal to the second valve 11 in such a manner that the second supply channel 9 changes from the open state to the closed state. In the embodiment, the control device 30 outputs the control signal to the second valve 11 in such a manner that the second supply channel 9 is closed when the detected temperature PV of the circulation fluid Fc does not reach the second set temperature SVh and the difference between the detected temperature PV and the second set temperature SVh becomes the prescribed value γ. That is, in the embodiment, the control device 30 outputs the control signal to the second valve 11 in such a manner that the second supply channel 9 is closed when the detected temperature PV of the circulation fluid Fc reaches the temperature [SVh−γ].

The control device 30 performs the opening and closing operation of the second valve 11 only once. Since the opening and closing operation of the second valve 11 is not performed many times, deterioration of the second valve 11 is controlled. Since the second valve 11 is the electromagnetic valve, it is possible to quickly open the second supply channel 9 and quickly supply the second fluid F2 to the tank 2. In addition, since the second valve 11 is the electromagnetic valve, it is possible to quickly close the second supply channel 9 and quickly stop the supply of the second fluid F2 to the tank 2. An appropriate amount of the second fluid F2 is quickly supplied to the circulation channel 3 by the opening and closing operation of the second valve 11. Since the appropriate amount of the second fluid F2 is quickly supplied to the circulation channel 3, the difference between the detected temperature PV of the circulation fluid Fc and the second set temperature SVh decreases in a short time.

The control device 30 outputs the control signal to the temperature adjuster 5 in such a manner that the temperature of the circulation fluid Fc supplied to the temperature adjustment target 100 becomes the second set temperature SVh when the second valve 11 closes the second supply channel 9. Since the temperature adjuster 5 includes the thermoelectric module 60, the temperature of the circulation fluid Fc can be adjusted with high accuracy.

In addition, the control device 30 controls the first valve 10 and adjusts the flow rate of the first fluid F1 supplied to the circulation channel 3 in such a manner that the temperature of the circulation fluid Fc supplied to the temperature adjustment target 100 becomes the second set temperature SVh when the second valve 11 closes the second supply channel 9. Since the first valve 10 is the proportional control valve, the flow rate of the first fluid F1 supplied to the circulation channel 3 can be adjusted with high accuracy. Since the flow rate of the first fluid F1 supplied to the circulation channel 3 is adjusted with high accuracy, the temperature of the circulation fluid Fc is adjusted with high accuracy.

In such a manner, in the embodiment, when the set temperature SV of the temperature adjustment target 100 is changed from the first set temperature SV1 to the second set temperature SVh, the opening and closing operation of the second valve 11 is performed in such a manner that the difference between the detected temperature PV of the circulation fluid Fc and the second set temperature SVh becomes small in a short time. After the temperature of the circulation fluid Fc is roughly adjusted by the opening and closing operation of the second valve 11, the temperature of the circulation fluid Fc is adjusted with high accuracy by one or both of the temperature adjuster 5 and the first fluid F1 the flow rate of which is adjusted with high accuracy.

After the second valve 11 opens the second supply channel 9, when a prescribed time elapses after the set temperature SV is changed from the first set temperature SV1 to the second set temperature SVh, the control device 30 may output the control signal to the second valve 11 in such a manner that the second supply channel 9 changes from the open state to a closed state. That is, at a time point is after a prescribed time from the time point t0, the second valve 11 may close the second supply channel 9, and adjustment of the temperature of the circulation fluid Fc by at least one of the temperature adjuster 5 and the first fluid F1 may be started. The prescribed time is a predetermined value.

[Effect]

As described above, according to the embodiment, the temperature control system 1A includes the circulation channel 3 including the temperature adjustment target 100, the second temperature adjustment unit 7 arranged outside the circulation channel 3, the second supply channel 9 that connects the circulation channel 3 and the second temperature adjustment unit 7, and the second valve 11 that is the electromagnetic valve (on-off valve) arranged in the second supply channel 9. When the set temperature SV of the temperature adjustment target 100 is changed from the first set temperature SV1 to the second set temperature SVh, the second valve 11 opens the second supply channel 9 only once, and closes the second supply channel 9 when the detected temperature PV reaches the temperature [SVh−γ]. A response speed of the second valve 11, which is the electromagnetic valve, is higher than a response speed of a three-way valve that is a proportional control valve, for example. Since the response speed of the second valve 11 is high, the time required for the difference between the detected temperature PV of the circulation fluid Fc flowing through the circulation channel 3 and the second set temperature SVh to become the prescribed value γ or smaller becomes short. Thus, when the set temperature SV of the temperature adjustment target 100 is changed from the first set temperature SV1 to the second set temperature SVh, the temperature of the circulation fluid Fc flowing through the circulation channel 3 is adjusted to the second set temperature SVh in a short time.

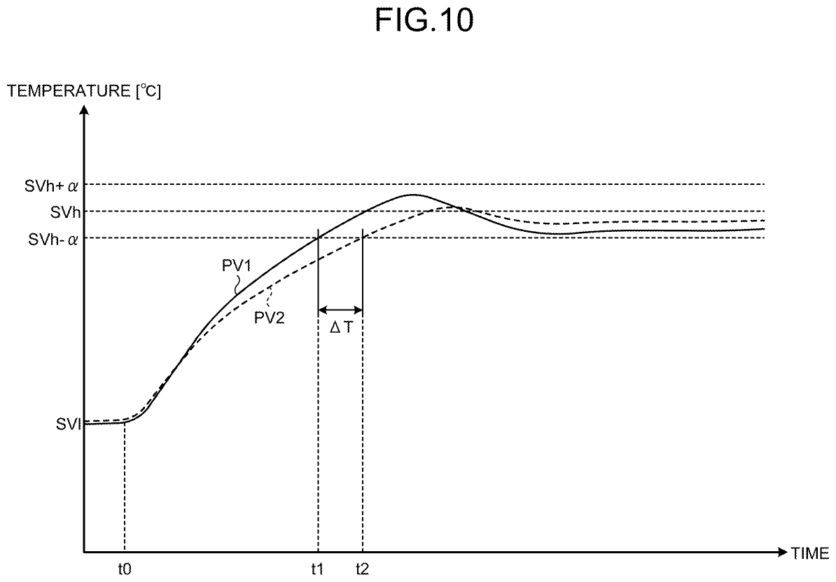

FIG. 10 is a graph illustrating the detected temperature PV of the circulation fluid Fc in each of a case where an electromagnetic valve is used as the second valve 11 and a case where a three-way valve is used as the second valve 11 according to the embodiment. In the graph illustrated in FIG. 10, a horizontal axis represents time, and a vertical axis represents the detected temperature PV. At the time point t0, the set temperature SV of the temperature adjustment target 100 is changed from the first set temperature SV1 to the second set temperature SVh. A line PV1 indicates the detected temperature PV of a case where the electromagnetic valve (on-off valve) is used as the second valve 11. A line PV2 indicates the detected temperature PV of a case where the three-way valve (proportional control valve) is used as the second valve 11. In a case where the electromagnetic valve is used as the second valve 11, the detected temperature PV reaches a process start temperature [SVh−α] at a time point t1. α is a predetermined arbitrary threshold. In a case where the three-way valve is used as the second valve 11, the detected temperature PV reaches the process start temperature [SVh−α] at a time point t2 that is later than the time point t1 for a time ΔT. In such a manner, in a case where the electromagnetic valve is used as the second valve 11, the detected temperature PV can reach the process start temperature [SVh−α] in a shorter time than a case where the three-way valve is used as the second valve 11.

The temperature adjuster 5 includes the thermoelectric module 60. As a result, the temperature adjuster 5 can highly accurately adjust the temperature of the circulation fluid Fc supplied to the temperature adjustment target 100.

The proportional control valve (three-way valve) is used as the first valve 10 arranged in the first supply channel 8. In the embodiment, the temperature adjustment target 100 is a wafer holder of a plasma processing device. The wafer holder is heated exclusively in the plasma processing. That is, a thermal disturbance is input to the temperature adjustment target 100. In a case where the temperature of the temperature adjustment target 100 to which the thermal disturbance is input is adjusted to the set temperature SV (SV1 or SVh), it is effective to supply the first fluid F1 having a low temperature to the circulation channel 3 at an appropriate flow rate. Thus, as the first valve 10, the proportional control valve (three-way valve) capable of highly accurately adjusting the flow rate of the first fluid F1 supplied from the first temperature adjustment unit 6 to the circulation channel 3 is used. Since the proportional control valve (three-way valve) is used as the first valve 10, the temperature of the temperature adjustment target 100 to which the thermal disturbance is input is appropriately adjusted to the set temperature SV (SV1 or SVh).

The first valve 10 is the three-way valve, and can be operated in such a manner that at least a part of the first fluid F1 delivered from the first temperature adjustment unit 6 to the first supply channel 8 is returned to the first temperature adjustment unit 6 via the first return channel 12. Accordingly, the first temperature adjustment unit 6 can be operated under a certain condition in both of a state in which the first fluid F1 is supplied to the circulation channel 3 and a state in which the first fluid F1 is not supplied thereto. Since the first temperature adjustment unit 6 operates under a certain condition, the temperature of the first fluid F1 delivered from the first temperature adjustment unit 6 is maintained at the first temperature T1. The temperature of the circulation fluid Fc flowing through the circulation channel 3 is adjusted with high accuracy only by the adjustment of the flow rate of the first fluid F1, which is supplied to the circulation channel 3, by the first valve 10.

The third valve 14 is arranged in the second 20 return channel 13. The third valve 14 is the electromagnetic valve (open valve). The third valve 14 can operate at a response speed equivalent to that of the second valve 11. The third valve 14 closes the second return channel 13 when the second valve 11 opens the second supply channel 9, and opens the second return channel 13 in such a manner that the second fluid F2 delivered from the second temperature adjustment unit 7 to the second supply channel 9 is returned to the second temperature adjustment unit 7 via the second return channel 13 when the second valve 11 closes the second supply channel 9. As a result, the second temperature adjustment unit 7 can be operated under a certain condition in both of a state in which the second fluid F2 is supplied to the circulation channel 3 and a state in which the second fluid F2 is not supplied thereto. Since the second temperature adjustment unit 7 operates under a certain condition, the temperature of the second fluid F2 delivered from the second temperature adjustment unit 7 is maintained at the second temperature T2. In a state in which the second temperature adjustment unit 7 operates under a certain condition, a state in which the second fluid F2 is supplied from the second temperature adjustment unit 7 to the circulation channel 3 and a state in which the second fluid F2 is returned from the second temperature adjustment unit 7 to the second temperature adjustment unit 7 via the second return channel 13 are switched.

The fourth valve 15 is arranged in the circulation channel 3. The fourth valve 15 is the electromagnetic valve (open valve). The fourth valve 15 can operate at a response speed equivalent to that of the second valve 11. The fourth valve 15 closes the circulation channel 3 when the second valve 11 opens the second supply channel 9, and opens the circulation channel 3 when the second valve 11 closes the second supply channel 9. When the second supply channel 9 is opened and the second fluid F2 is supplied to the tank 2, the return portion 3B of the circulation channel 3 is closed and the supply of the circulation fluid Fc to the tank 2 is controlled, whereby overflow of the circulation fluid Fc from the tank 2 is controlled. In the tank 2, the circulation fluid Fc and the second fluid F2 are appropriately mixed. When the second supply channel 9 is closed and the second fluid F2 is not supplied to the tank 2, the return portion 3B of the circulation channel 3 is opened, whereby the circulation fluid Fc appropriately circulates in the circulation channel 3.

The fifth valve 20 is arranged in the first overflow channel 17, and the sixth valve 21 is arranged in the second overflow channel 18. Each of the fifth valve 20 and the sixth valve 21 is the electromagnetic valve (open valve). Each of the fifth valve 20 and the sixth valve 21 can operate at a response speed equivalent to that of the second valve 11.

The fifth valve 20 closes the first overflow channel 17 when the second valve 11 opens the second supply channel 9. As a result, the circulation fluid Fc that overflows from the tank 2 when the second fluid F2 is supplied from the second temperature adjustment unit 7 to the circulation channel 3 is prevented from being supplied to the first temperature adjustment unit 6. The fifth valve 20 opens the first overflow channel 17 when the second valve 11 closes the second supply channel 9. As a result, the circulation fluid Fc that overflows from the tank 2 when the first fluid F1 is supplied from the first temperature adjustment unit 6 to the circulation channel 3 is supplied to the first temperature adjustment unit 6.

The sixth valve 21 opens the second overflow channel 18 when the second valve 11 opens the second supply channel 9. As a result, the circulation fluid Fc that overflows from the tank 2 when the second fluid F2 is supplied from the second temperature adjustment unit 7 to the circulation channel 3 is supplied to the second temperature adjustment unit 7. The sixth valve 21 closes the second overflow channel 18 when the second valve 11 closes the second supply channel 9. As a result, the circulation fluid Fc that overflows from the tank 2 when the first fluid F1 is supplied from the first temperature adjustment unit 6 to the circulation channel 3 is prevented from being supplied to the second temperature adjustment unit 7.

### OTHER EMBODIMENTS

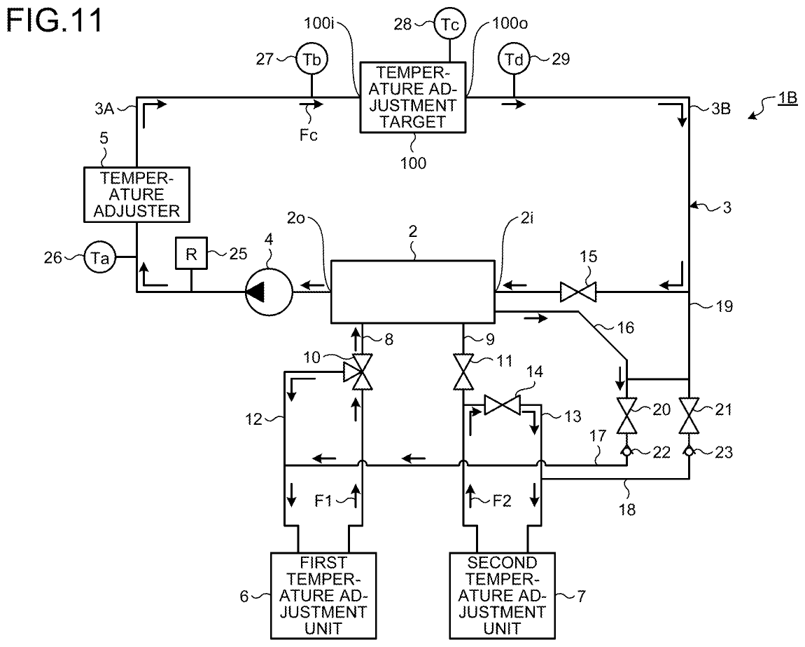

FIG. 1I is a configuration diagram illustrating a temperature control system 1B according to an embodiment. As illustrated in FIG. 11, a ninth valve 24 may be omitted.

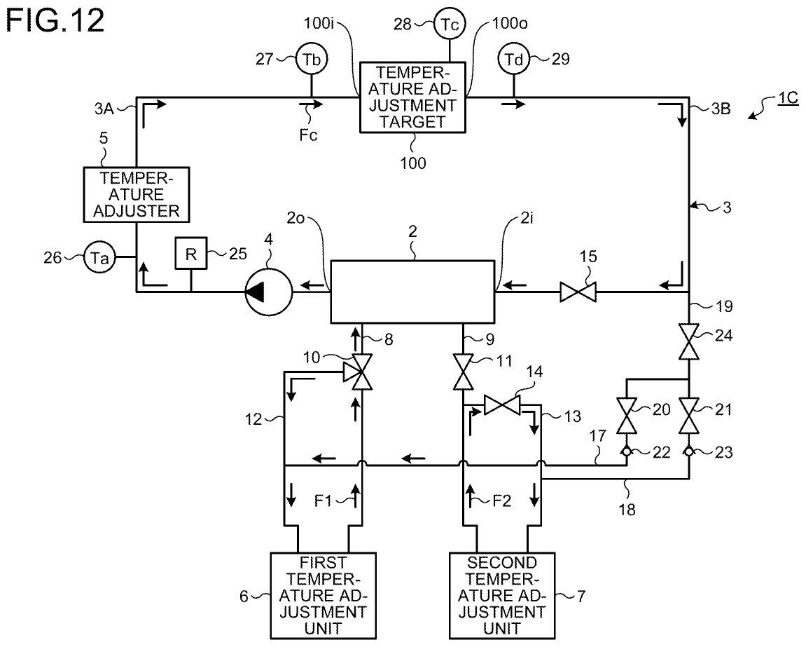

FIG. 12 is a configuration diagram illustrating a temperature control system 1C according to an embodiment. As illustrated in FIG. 12, an overflow channel 16 may be omitted.

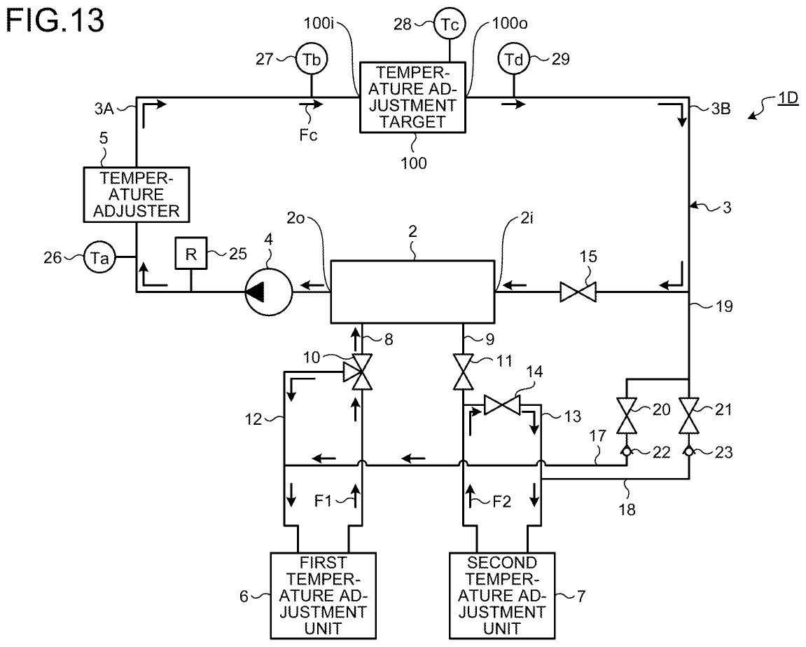

FIG. 13 is a configuration diagram illustrating a temperature control system 1D according to an embodiment. As illustrated in FIG. 13, each of a ninth valve 24 and an overflow channel 16 may be omitted.

In the above-described embodiment, a tank 2 may be omitted. That is, an entire circulation channel 3 may be configured by a pipeline.

### REFERENCE SIGNS LIST

1A TEMPERATURE CONTROL SYSTEM
1B TEMPERATURE CONTROL SYSTEM
1C TEMPERATURE CONTROL SYSTEM
1D TEMPERATURE CONTROL SYSTEM
2 TANK
2o OUTLET
2i INLET
3 CIRCULATION CHANNEL
3A SUPPLY PORTION
3B RETURN PORTION
4 CIRCULATION PUMP
TEMPERATURE ADJUSTER
6 FIRST TEMPERATURE ADJUSTMENT UNIT
7 SECOND TEMPERATURE ADJUSTMENT UNIT
8 FIRST SUPPLY CHANNEL
9 SECOND SUPPLY CHANNEL
10 FIRST VALVE
11 SECOND VALVE
12 FIRST RETURN CHANNEL
13 SECOND RETURN CHANNEL
14 THIRD VALVE
15 FOURTH VALVE
16 OVERFLOW CHANNEL
17 FIRST OVERFLOW CHANNEL
18 SECOND OVERFLOW CHANNEL
19 BYPASS CHANNEL
20 FIFTH VALVE
21 SIXTH VALVE
22 SEVENTH VALVE
23 EIGHTH VALVE
24 NINTH VALVE
25 FLOW RATE SENSOR
26 TEMPERATURE SENSOR
27 TEMPERATURE SENSOR
28 TEMPERATURE SENSOR
29 TEMPERATURE SENSOR
30 CONTROL DEVICE
40 MAIN BODY MEMBER
41 INLET
42 TEMPERATURE ADJUSTMENT CHANNEL
43 OUTLET
44 HEAT EXCHANGE PLATE
45 DRIVE CIRCUIT
50 TEMPERATURE ADJUSTMENT PORTION
51 CASE
60 THERMOELECTRIC MODULE
61 FIRST ELECTRODE
62 SECOND ELECTRODE
63 THERMOELECTRIC SEMICONDUCTOR ELEMENT
63P p-TYPE THERMOELECTRIC SEMICONDUCTOR ELEMENT
63N n-TYPE THERMOELECTRIC SEMICONDUCTOR ELEMENT
100 TEMPERATURE ADJUSTMENT TARGET
100i INLET
100c OUTLET
Ca LINE
Cb LINE
Cc LINE
Fc CIRCULATION FLUID
F1 FIRST FLUID
F2 SECOND FLUID
PV DETECTED TEMPERATURE
PV1 LINE
PV2 LINE
R FLOW RATE
SV SET TEMPERATURE
SV1 FIRST SET TEMPERATURE
SVh SECOND SET TEMPERATURE
Ta TEMPERATURE
Tb TEMPERATURE
Tc TEMPERATURE
Td TEMPERATURE
t0 TIME POINT
t1 TIME POINT
t2 TIME POINT
ts TIME POINT
γ PRESCRIBED VALUE
δ THRESHOLD
ΔT TIME

1. A temperature control system comprising:
a circulation channel which includes a temperature adjustment target and through which a circulation fluid that adjusts a temperature of the temperature adjustment target flows;
a temperature adjuster that is arranged in the circulation channel and that adjusts a temperature of the circulation fluid supplied to the temperature adjustment target;
a first temperature adjustment unit that is connected to the circulation channel via a first supply channel and that delivers a first fluid having a first temperature;
a second temperature adjustment unit that is connected to the circulation channel via a second supply channel and that delivers a second fluid having a second temperature higher than the first temperature;
a first valve arranged in the first supply channel; and
a second valve arranged in the second supply channel,
wherein the second valve is an electromagnetic valve, and closes the second supply channel after opening the second supply channel when a set temperature of the temperature adjustment target is changed from a first set temperature to a second set temperature higher than the first set temperature.

2. The temperature control system according to claim 1, wherein the second valve closes the second supply channel when a difference between a detected temperature of the circulation fluid and the second set temperature becomes equal to or smaller than a prescribed value or when a prescribed time elapses after the set temperature is changed to the second set temperature after the second supply channel is opened.

3. The temperature control system according to claim 1, wherein the temperature adjuster includes a thermoelectric module, and adjusts the temperature of the circulation fluid in such a manner that the temperature of the circulation fluid supplied to the temperature adjustment target becomes the second set temperature when the second valve closes the second supply channel.

4. The temperature control system according to claim 1, wherein the first valve is a proportional control valve, and adjusts a flow rate of the first fluid supplied to the circulation channel in such a manner that the temperature of the circulation fluid supplied to the temperature adjustment target becomes the second set temperature when the second valve closes the second supply channel.

5. The temperature control system according to claim 4, wherein the first valve is a three-way valve,
a first return channel that connects the first valve and the first temperature adjustment unit is further included, and
the first valve can be operated in such a manner that at least a part of the first fluid delivered from the first temperature adjustment unit to the first supply channel is returned to the first temperature adjustment unit via the first return channel.

6. The temperature control system according to claim 1, further comprising:
a second return channel that connects the second supply channel between the second valve and the second temperature adjustment unit and the second temperature adjustment unit, and
a third valve arranged in the second return channel, wherein
the third valve is an electromagnetic valve, and closes the second return channel when the second valve opens the second supply channel, and opens the second return channel in such a manner that the second fluid delivered from the second temperature adjustment unit to the second supply channel is returned to the second temperature adjustment unit via the second return channel when the second valve closes the second supply channel.

7. The temperature control system according to claim 1, further comprising a fourth valve arranged in the circulation channel,
wherein the fourth valve is an electromagnetic valve, and closes the circulation channel when the second valve opens the second supply channel, and opens the circulation channel when the second valve closes the second supply channel.

8. The temperature control system according to claim 7, wherein the circulation channel includes a tank in which the circulation fluid and at least one of the first fluid and the second fluid are mixed,
each of the first supply channel and the second supply channel is connected to the tank, and
the fourth valve is arranged in the circulation channel between an outlet of the temperature adjustment target and an inlet of the tank.

9. The temperature control system according to claim 1, further comprising:
a first overflow channel that connects the circulation channel and the first temperature adjustment unit;
a second overflow channel that connects the circulation channel and the second temperature adjustment unit;
a fifth valve arranged in the first overflow channel; and
a sixth valve arranged in the second overflow channel,
wherein the fifth valve is an electromagnetic valve, and closes the first overflow channel when the second valve opens the second supply channel, and opens the first overflow channel when the second valve closes the second supply channel, and
wherein the sixth valve is an electromagnetic valve, and opens the second overflow channel when the second valve opens the second supply channel, and closes the second overflow channel when the second valve closes the second supply channel.
